(19) United States
(12) Patent Application Publication
(10) Pub. No.: US 2016/0141280 A1
(43) Pub. Date: May 19, 2016

(54) Device-Embedded Image Sensor, And Wafer-Level Method For Fabricating Same

(71) Applicant: OmniVision Technologies, Inc., Santa Clara, CA (US)

(72) Inventors: Wei-Feng Lin, Hsinchu City (TW); Chi-Chih Huang, Hsinchu City (TW)

(21) Appl. No.: 14/542,195

(22) Filed: Nov. 14, 2014

(51) Int. Cl. H01L 25/18; H01L 25/00; H01L 27/146

(52) U.S. Cl. CPC H01L 25/18; H01L 27/14643; H01L 27/14636; H01L 27/14632; H01L 27/14687; H01L 27/14689; H01L 25/50

(57) ABSTRACT

A device-embedded image sensor includes an image sensor formed in a first semiconductor substrate; a top conductive pad formed on a top surface of the first semiconductor substrate; and a semiconductor device formed in a second semiconductor substrate bonded to a bottom surface of the first semiconductor substrate, the semiconductor device electrically connected to the top conductive pad. A method for fabricating a device-embedded image sensor from a CMOS image sensor wafer assembly that includes an image sensor and a conductive pad. The method includes exposing the conductive pad; forming an isolation layer; exposing a surface of each conductive pad; forming a patterned redistribution layer (RDL) having a plurality of RDL elements on the isolation layer; electrically isolating adjacent RDL elements; and laminating the CMOS image sensor wafer assembly and a semiconductor device wafer to form undiced device-embedded image sensors.

### BACKGROUND

The present invention relates to image sensors, application-specific integrated circuits (ASICs), and specifically, ASICs embedded beneath image sensors.

Camera modules in products such as stand-alone digital cameras, mobile devices, automotive components, and medical devices often include a CMOS image sensor. The image sensor converts light imaged by a camera lens into a digital signal that is converted into a displayed image and/or file containing the image data. The image sensor is typically surface-mounted onto a printed circuit board (PCB). The PCB also includes an ASIC designed to cooperate with the image sensor and handle data/image processing functions. Possible ASIC functions include image processing, video processing and streaming, and high-speed data transfer.

FIG. 1 is a plan view of a prior-art camera module PCB 102 that includes an image sensor 124 and an ASIC chip 126. The above-mentioned products include a camera module PCB similar to PCB 102. FIG. 2 is a cross-sectional view of camera module PCB 102 along cross-section 2-2′. In FIGS. 1 and 2, arrays of wire bonds 134 and wire bonds 136 electrically connect image sensor 124 and ASIC chip 126 to camera module PCB 102, respectively. For clarity of illustration, not all wire bonds 134 and 136 in FIG. 1 include a lead line and a reference numeral.

Decreasing the camera module size while maintaining camera functionality can lower production costs and enhance product utility. Yet, decreasing the size of either or both of the image sensor and the ASIC constrains functionality of both. One approach to decreasing camera module size is to stack the image sensor die and the ASIC die, as disclosed, for example, in U.S. Pat. No. 7,633,231 to Chang et al.

### SUMMARY OF THE INVENTION

A limitation of the conventional stacked-die image sensors mentioned above is that the step of incorporating ASIC dies onto image sensors on a wafer is not performed wafer-level. Rather, individual ASIC dies are applied to each image sensor. For some applications, these stacked-die image sensors have a second limitation: the external electrical connections to the image sensor and ASIC are in a common plane other than the plane of the image sensor. The stacked-die image sensors and associated methods disclosed herein overcome these limitations.

A device-embedded image sensor is disclosed. The device-embedded image sensor includes image sensor formed on a top surface of a first semiconductor substrate, a conductive pad formed on the top surface and a semiconductor device formed in a second semiconductor substrate bonded to a bottom surface of the first semiconductor substrate, i.e. beneath the image sensor. The semiconductor device is electrically connected to the conductive pad.

A method for fabricating a device-embedded image sensor from a CMOS image sensor wafer assembly is also disclosed. The CMOS image sensor wafer assembly includes an image sensor formed in a semiconductor wafer and a conductive pad having an exposed surface on a top side of the semiconductor wafer. The method includes exposing the conductive pad by removing at least a portion of the semiconductor wafer and forming an isolation layer over the removed portion of the semiconductor wafer. The method also includes exposing a surface of the conductive pad by removing at least a portion of the isolation layer in contact thereto, and forming a patterned redistribution layer (RDL) having a plurality of RDL elements on the isolation layer such that each conductive pad is electrically connected to one of the plurality of RDL elements. The method also includes electrically isolating adjacent RDL elements and laminating the CMOS image sensor wafer assembly and a semiconductor device wafer to form undiced device-embedded image sensors.

### BRIEF DESCRIPTION OF THE FIGURES

FIG. 1 is a plan view of a prior-art camera module PCB that includes a CMOS image sensor and an ASIC.

FIG. 2 is a cross-sectional view of the camera module PCB of FIG. 1.

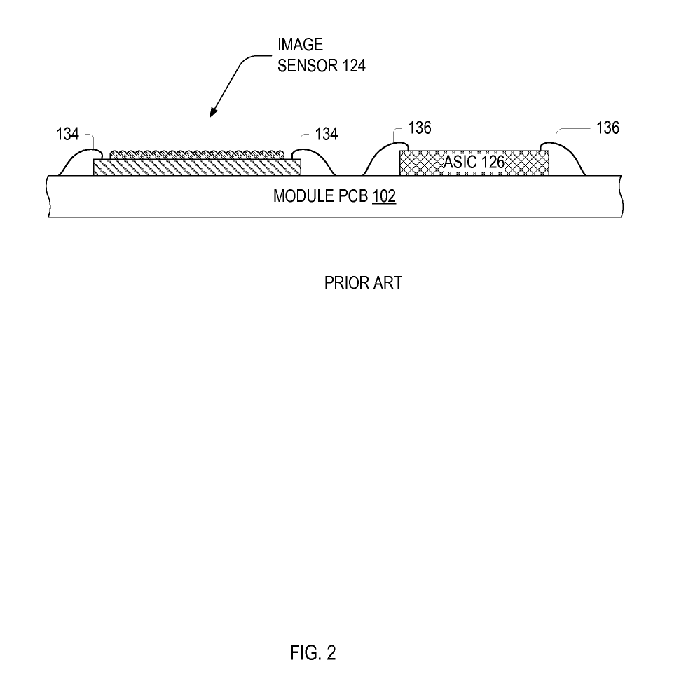

FIG. 3 is a plan view of a device-embedded image sensor mounted on a PCB, in an embodiment.

FIG. 4 is a cross-sectional view of the device-embedded image sensor of FIG. 3.

FIG. 5 is a flowchart illustrating an exemplary method for fabricating a wafer-level chip-scale-packaged image sensor with an embedded semiconductor device, in an embodiment.

FIG. 6 is a cross-sectional view of a CMOS image sensor wafer assembly that includes two encapsulated image sensors formed on a semiconductor wafer and covered by a protective substrate, in an embodiment.

FIG. 7 is a cross-sectional view of the CMOS image sensor wafer assembly of FIG. 6 with a thinned the semiconductor wafer, in an embodiment.

FIG. 8 is a cross-sectional view of the CMOS image sensor wafer assembly of FIG. 7 with a plurality of conductive pads exposed, in an embodiment.

FIG. 9 is a cross-sectional view of the CMOS image sensor wafer assembly of FIG. 8 with an isolation layer blanket-deposited on the semiconductor wafer, in an embodiment.

FIG. 10 is a cross-sectional view of the CMOS image sensor wafer assembly of FIG. 9 with exposed conductive pads, in an embodiment.

FIG. 11 is a cross-sectional view of the CMOS image sensor wafer assembly of FIG. 10 with a patterned redistribution layer (RDL) on the isolation layer, in an embodiment.

FIG. 12 is a cross-sectional view of the CMOS image sensor wafer assembly of FIG. 11 with a plurality of isolation layer elements formed in gaps of the patterned redistribution layer, in an embodiment.

FIG. 13 is a cross-sectional view of the CMOS image sensor wafer assembly of FIG. 12 with the CMOS image sensor wafer assembly and an ASIC wafer laminated with a layer of anisotropic conductive film, in an embodiment.

FIG. 14 is a perspective view of the CMOS image sensor wafer assembly of FIG. 13, in an embodiment.

FIG. 15 is a cross-sectional view of two device-embedded image sensors resulting from dicing the CMOS image sensor wafer assembly of FIG. 13, in an embodiment.

FIG. 16 is a cross-sectional view of a device-embedded image sensor of FIG. 15 with the protective substrate removed, in an embodiment.

FIG. 17 is a cross-sectional view of the device-embedded image sensor of FIG. 16, mounted on a PCB, in an embodiment.

### DETAILED DESCRIPTION

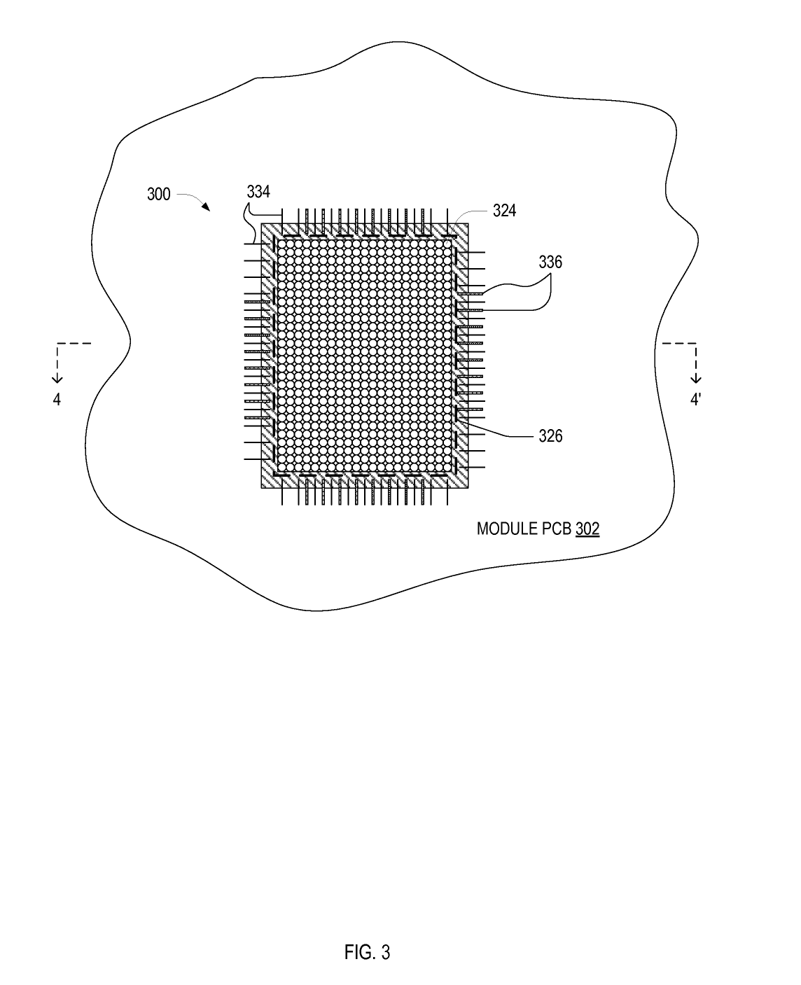

FIG. 3 is a plan view of a device-embedded image sensor 300 on a camera module PCB 302. Device-embedded image sensor 300 includes an ASIC 326 beneath an image sensor 324. Image sensor 324 is for example a CMOS image sensor. Wire bonds 334 electrically connect device-embedded image sensor 300 and ASIC 326 to a camera module PCB 302.

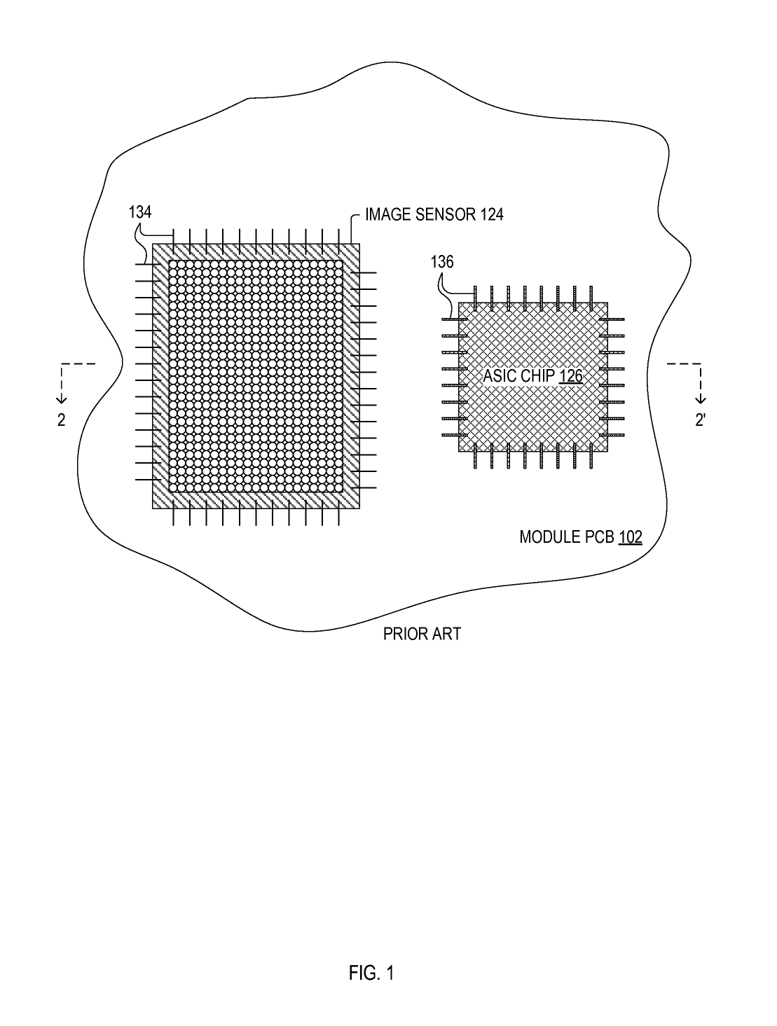

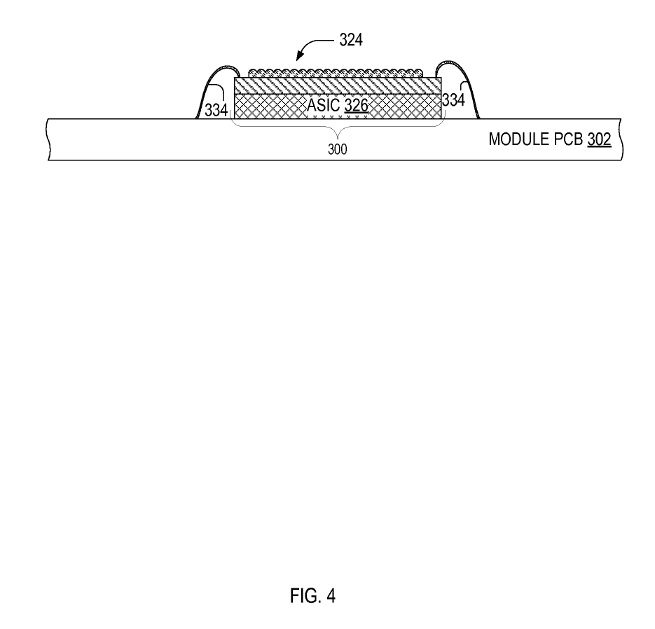

FIG. 4 is a cross-sectional view of a device-embedded image sensor 300 corresponding to cross-section 4-4′. Comparing FIG. 3 to FIG. 1 illustrates that device-embedded image sensor 300 has the combined functionality of image sensor 124 and ASIC 126, while having a significantly smaller device footprint.

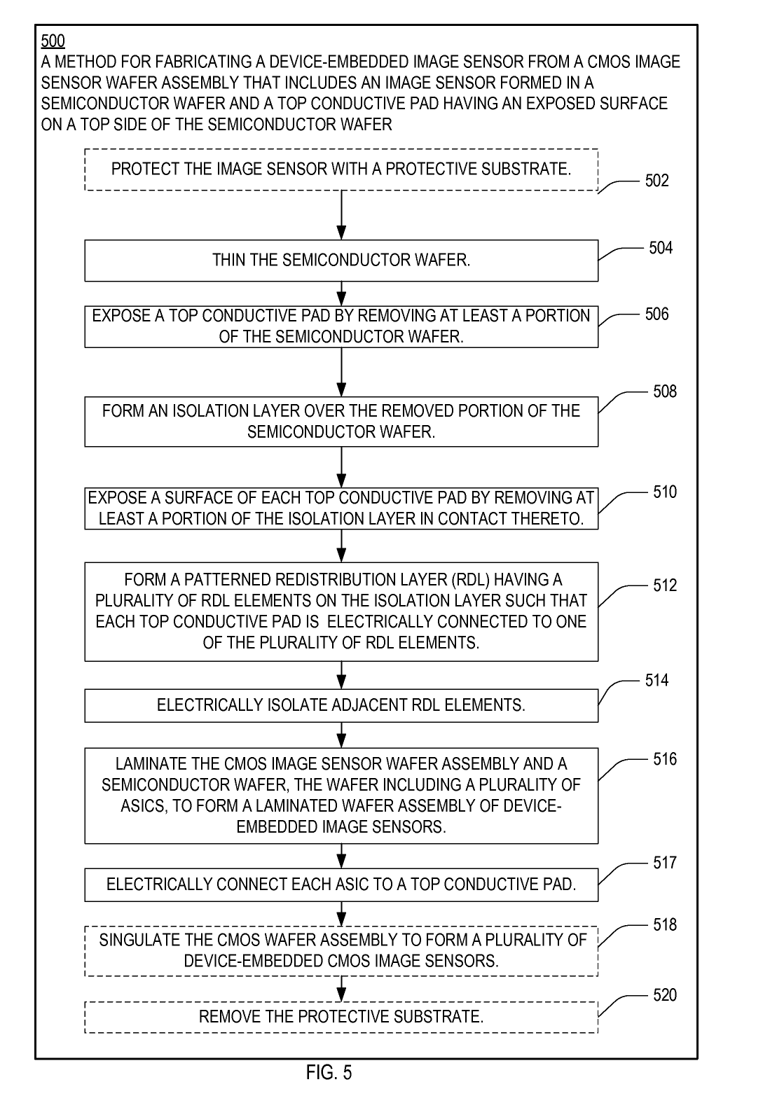

FIG. 5 is a flowchart illustrating an exemplary wafer-level method 500 for fabricating a device-embedded image sensor from a CMOS image sensor wafer assembly. The CMOS image sensor wafer assembly includes an image sensor formed on a top surface of a semiconductor wafer and a top conductive pad wire-bondable from above the top surface of the semiconductor wafer. Method 500 may be used to fabricate device-embedded image sensor 300, for example.

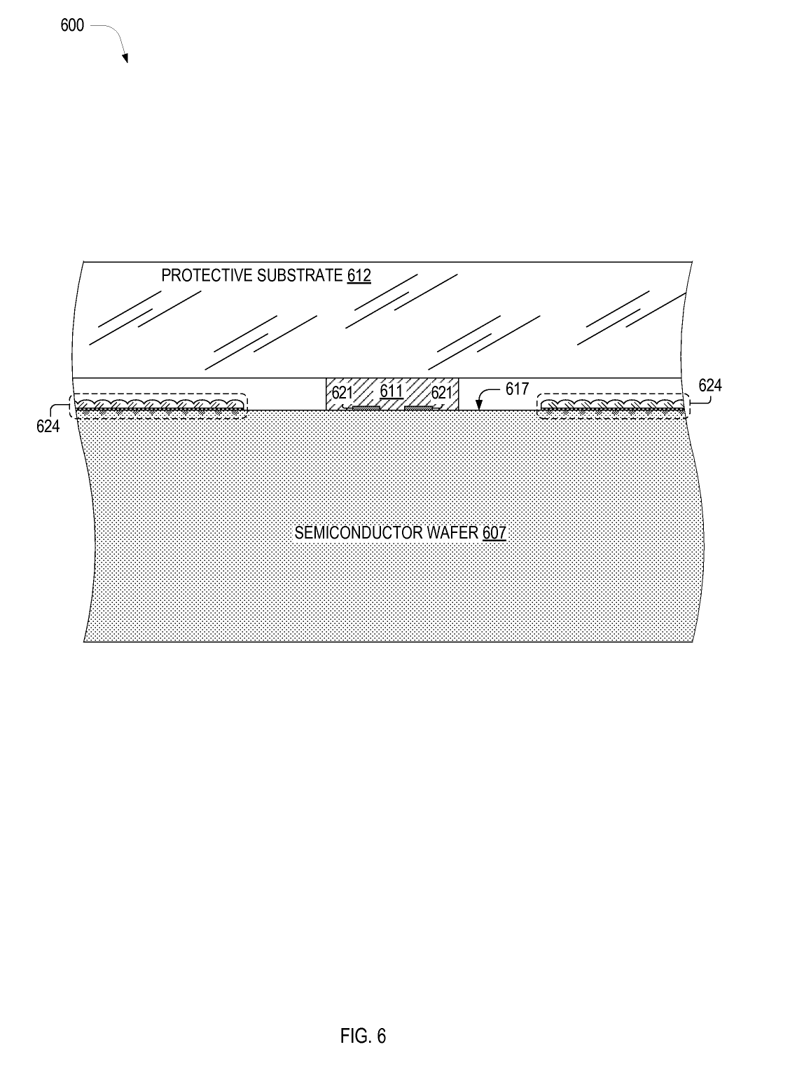

FIGS. 6-17 illustratively represent the results of method 500. The semiconductor device is shown as an ASIC. The semiconductor device may be other than an ASIC, a memory module for example, without departing from the scope hereof. FIG. 5 and FIGS. 6-17 are best viewed together with the following description.

FIG. 6 is a cross-sectional view of a CMOS image sensor wafer assembly 600. CMOS image sensor wafer assembly 600 includes two image sensors 624 formed on a top surface of a semiconductor wafer 607. Spacers 611 and a protective substrate 612 encapsulate image sensors 624. Examples of protective substrate 612 include, but are not limited to, a carrier glass wafer or a film. Image sensors 624 and spacers 611 shown in FIGS. 6-13 are part of respective arrays of image sensors 624 and spacers 611, not shown in FIGS. 6-13. CMOS image sensor wafer assembly 600 also includes top conductive pads 621 that, absent protective substrate 612, are wire-bondable from above a top surface 617 of semiconductor wafer 607.

FIG. 6 shows two top conductive pads 621 on top surface 617 of semiconductor wafer 607. An intermediate material layer, such as a portion of spacer 611, may be between top conductive pads 621 and semiconductor wafer 607, such that one of top conductive pads 621 is not directly on a top surface of semiconductor wafer 607, without departing from the scope hereof. FIG. 6 shows a portion of spacer 611 between each top conductive pad 621 and protective substrate 612. An embodiment of CMOS image sensor wafer assembly 600 having no portion of spacer 611 between each top conductive pad 621 and protective substrate 612 does not depart from the scope hereof.

Step 502 is optional. If included, in step 502, method 500 protects the image sensor with a protective substrate. The protective substrate spans the image sensor and is attached to each of a plurality of dams, which are formed on the same side of the semiconductor wafer as the image sensors. Each dam includes a top conductive pad.

In an example of step 502, method 500 protects image sensors 624 with protective substrate 612, as shown in FIG. 6. In FIG. 6, image sensors 624 are enclosed by dashed-line boxes. For clarity of illustration, the dashed-line boxes are omitted in subsequent figures.

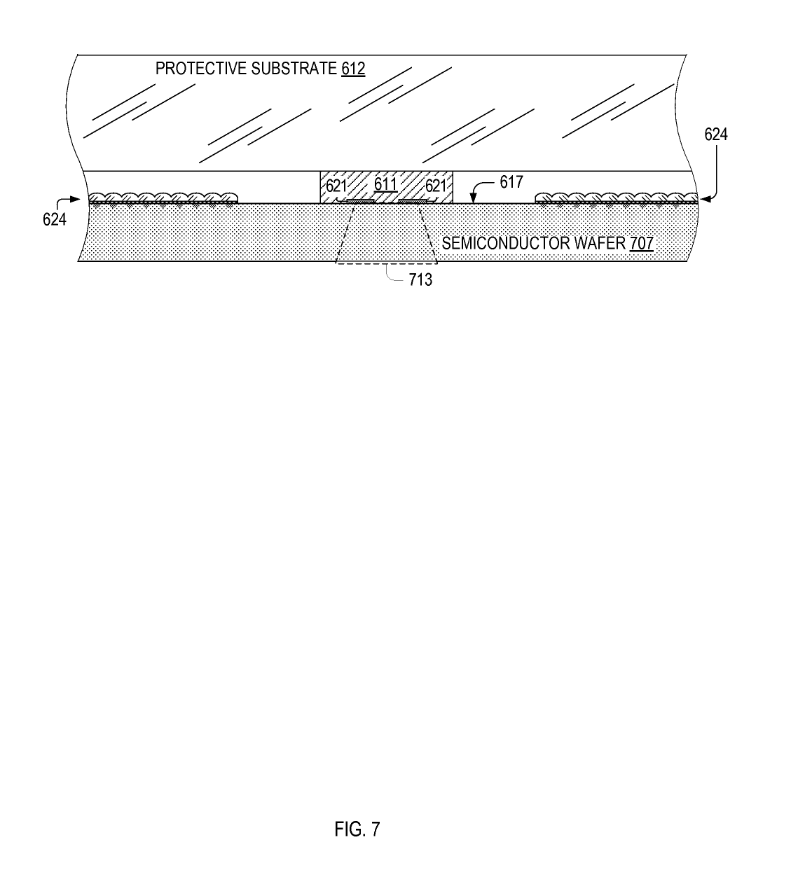

In step 504, method 500 thins the semiconductor wafer from beneath its top surface. In an example of step 504, method 500 thins semiconductor wafer 607 from beneath top surface 617 to yield a thinned semiconductor wafer 707, as shown in FIG. 7. FIG. 7 is a cross-sectional view of encapsulated image sensors 624 after step 504 of method 500. Semiconductor wafer 607 may be thinned by wafer backgrinding, etching, or other methods known in the art.

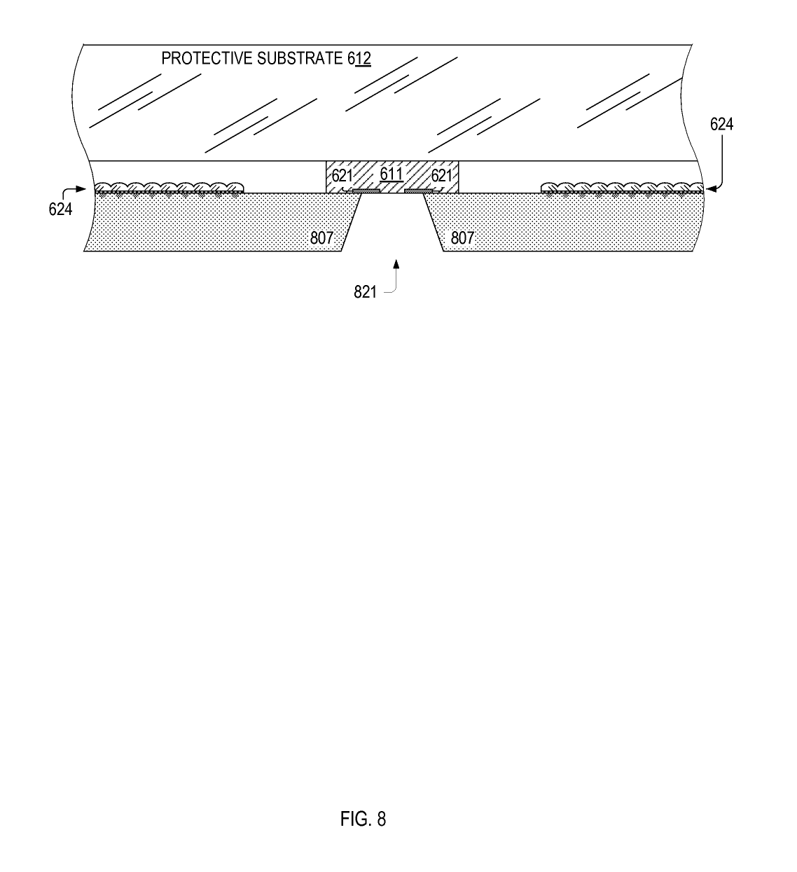

In step 506, method 500 exposes a top conductive pad by removing at least a portion of the semiconductor wafer. In an example of step 506, method 500 forms one or more notches 821 that expose top conductive pads 621, as shown in FIG. 8. FIG. 8 is a cross-sectional view of encapsulated image sensors 624, after step 506 of method 500. Notch 821 may be formed by etching thinned semiconductor wafer 707 through a photolithographically patterned photoresist, for example. Step 506 may employ microfabrication etching technologies and methods including isotropic etching, anisotropic etching, wet etching, dry etching (e.g., reactive-ion etching, sputter etching, vapor-phase etching) and others known in the art. Semiconductor wafer 807 is semiconductor wafer 707 with a wafer portion 713 removed.

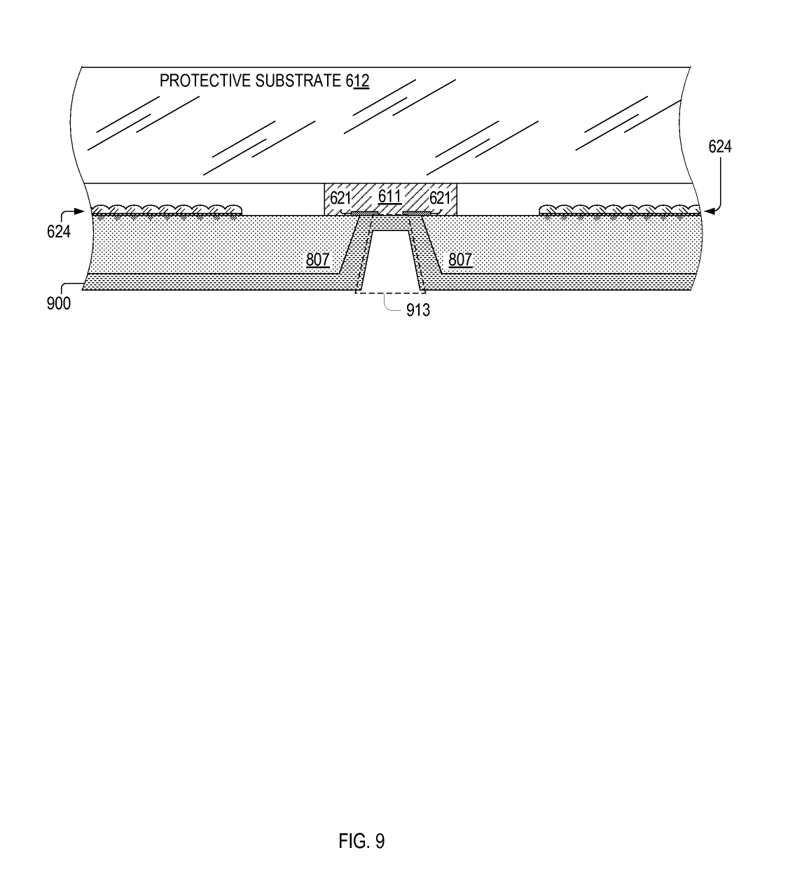

In step 508, method 500 forms an isolation layer over the removed portion of the semiconductor wafer. In an example of step 510, method 500 blanket-deposits an isolation layer 900 on semiconductor wafer 807 and exposed regions of spacers 611 and top conductive pads 621, as shown in FIG. 9. It should be appreciated that an intermediate layer may be between isolation layer 900 and semiconductor wafer 807 without departing from the scope hereof.

FIG. 9 is a cross-sectional view of encapsulated image sensors 624, after step 508 of method 500, which covers top conductive pads 621 with the isolation layer such that they are no longer exposed. Isolation layer 900 may be an oxide such as silicon dioxide, formed for example, by chemical vapor deposition or photochemical deposition or an organic material formed by coating or spray. Other layer deposition methods may be used without departing from the scope hereof.

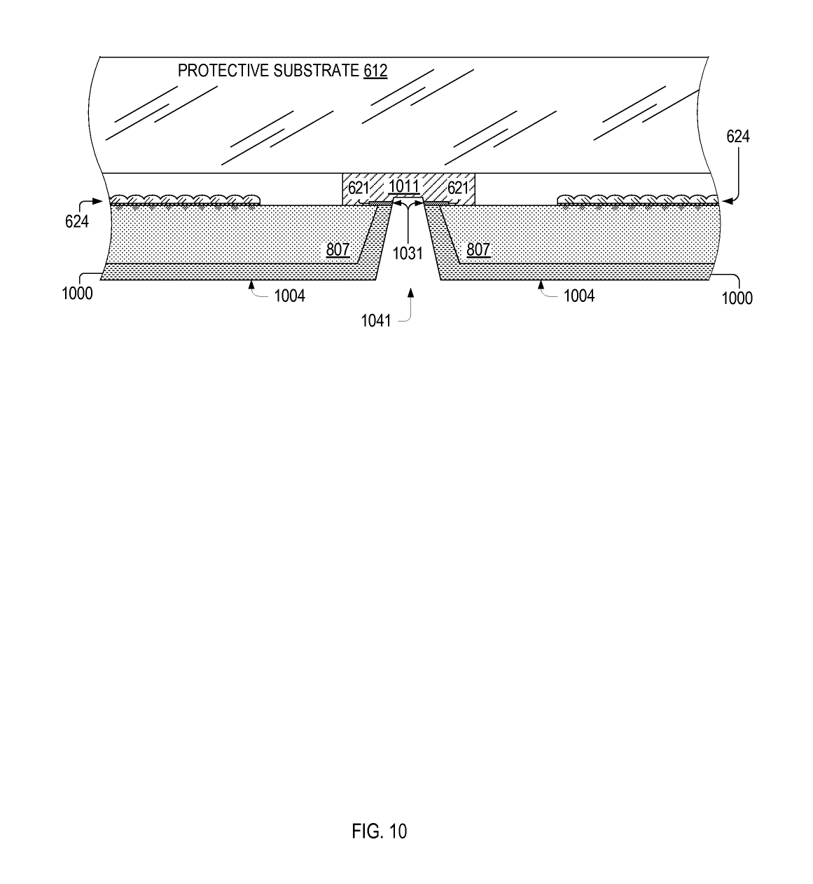

In step 510, method 500 exposes a surface of each top conductive pad by removing at least a portion of the isolation layer in contact thereto. In an example of step 510, method 500 exposes a surface 1031 of each top conductive pad 621, as shown in FIG. 10. FIG. 10 is a cross-sectional view of encapsulated image sensors 624, after step 510 of method 500. In this example of step 510, the step of reexposing the top conductive pads includes forming a notch 1041 beneath each spacer 611 and removing portions of top conductive pads 621 to expose conductive pad surfaces 1031. Spacer 1011 is spacer 611 with a region between top conductive pads 621 removed. Isolation layer 1000 is isolation layer 900 with an isolation layer portion 913 (FIG. 9) removed. A surface 1004 of isolation layer 1000 is opposite protective substrate 612.

In an embodiment of method 500, step 510 includes applying a patterned photoresist to the semiconductor wafer surface and etching notches therein. Etching may employ similar technologies and methods discussed regarding step 506. In an alternative to step 510, method 500 exposes a surface of each top conductive pad 621 by forming a through-silicon via (TSV) through semiconductor wafer 607.

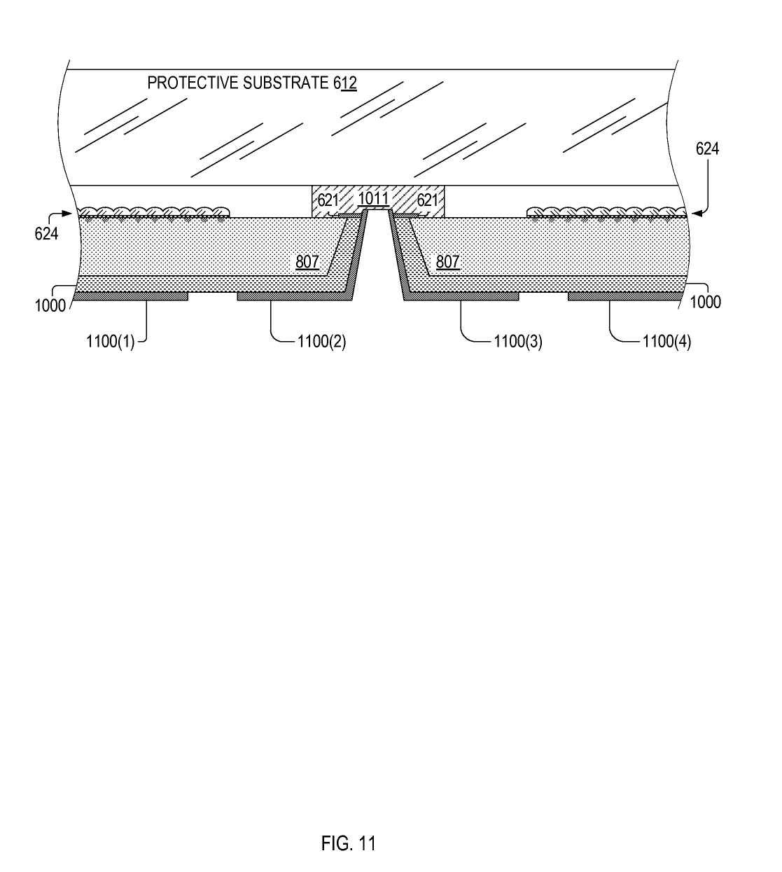

In step 512, method 500 forms a patterned redistribution layer (RDL) having a plurality of RDL elements on the isolation layer such that each top conductive pad is electrically connected to one of the plurality of RDL elements. In an example of step 512, method 500 forms a patterned redistribution layer (RDL) 1100 on surface 1004 of isolation layer 1000, as shown in FIG. 11.

FIG. 11 is a cross-sectional view of encapsulated image sensors 624, after step 512 of method 500. RDL 1100 includes RDL elements 1100(1-4). RDL elements 1100(2) and 1100(3) are each electrically connected to a different top conductive pad 621, as shown in FIG. 11. Hereafter, RDL elements 1100(2) and 1100(3) will be discussed as parts of their respective top conductive pads 621. RDL 1100 may be formed of one or more of Al, an Al—Cu alloy, and Cu, and has a metal finish formed of a nickel layer and a gold layer, as known in the art.

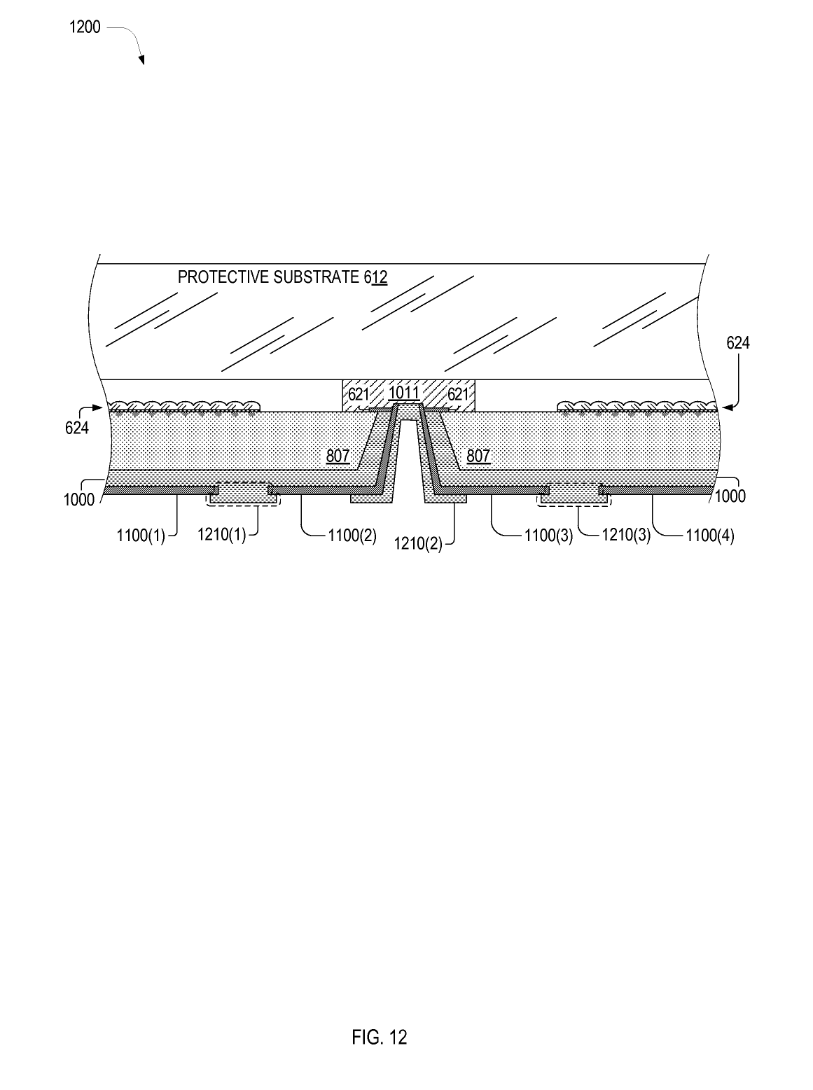

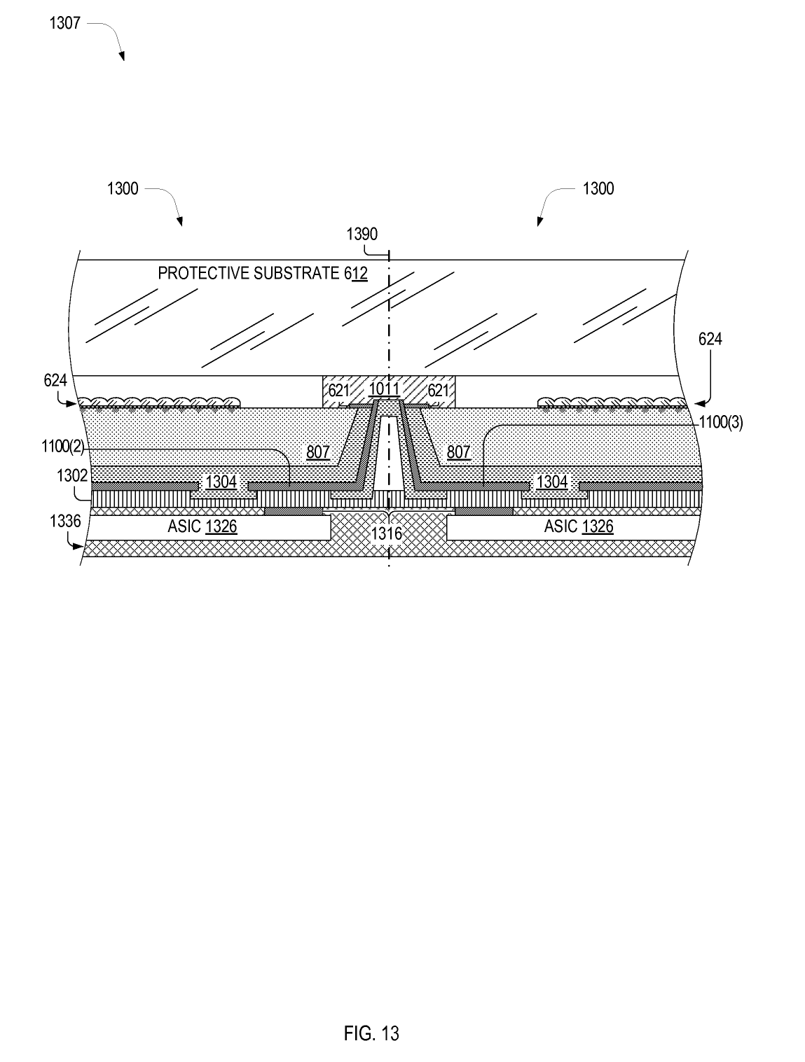

In step 514, method 500 electrically isolates adjacent RDL elements formed in step 512. In an example of step 514, method 500 isolates adjacent RDL elements 1100 from each other by the application of isolation layer elements 1210, for example, isolation layer elements 1210(1-3) are applied to parts of isolation layer 1000 and on RDL elements 1100, resulting in a CMOS image sensor wafer assembly 1200, as shown in FIG. 12. In an embodiment of method 500, shown in FIG. 12, isolation layer 1000 and isolation layer elements 1210 may be formed of the same material, and together form an isolation layer 1304, shown in FIG. 13. In a different embodiment, isolation layer 1000 and isolation layer elements 1210 are formed of different materials. FIG. 12 is a cross-sectional view of encapsulated image sensors 624 within a CMOS image sensor wafer assembly 600, after step 514 of method 500.

In step 516, method 500 laminates the CMOS image sensor wafer assembly and a semiconductor wafer to form a laminated wafer assembly of device-embedded image sensors. In an example of step 516, method 500 laminates CMOS image sensor wafer assembly 1200 and a bottom semiconductor wafer 1336 to form a laminated wafer assembly 1307.

Laminated wafer assembly 1307 is part of undiced device-embedded image sensors 1300, as shown in FIG. 13. Bottom semiconductor wafer 1336 includes a plurality of ASICs 1326. Each ASIC 1326 includes a bottom conductive pad 1316 formed on a bottom surface of semiconductor wafer 807.

It should be appreciated that an intermediate layer may be between bottom conductive pad 1316 and semiconductor wafer 807 without departing from the scope hereof. ASIC 1326 may be replaced with different semiconductor device, such as a memory module, without departing from the scope hereof.

In step 517, method 500 electrically connects each ASIC to a top conductive pad. In an example of step 517, a layer of anisotropic conductive film (ACF) 1302 electrically connects each ASIC 1326, via a bottom conductive pad 1316 thereon and a respective RDL element 1100, to a top conductive pad 621. FIG. 13 includes a dicing plane 1390 representing where optional step 518 singulates laminated wafer assembly 1307, as discussed below.

In an embodiment of method 500, a single step includes both steps 516 and 517. In an alternative to step 517, ACF 1302 is replaced with an adhesive for connecting bottom semiconductor wafer 1336 and CMOS image sensor wafer assembly 1200, and a conducting element between each bottom conductive pad 1316 and a respective RDL element 1100 above it.

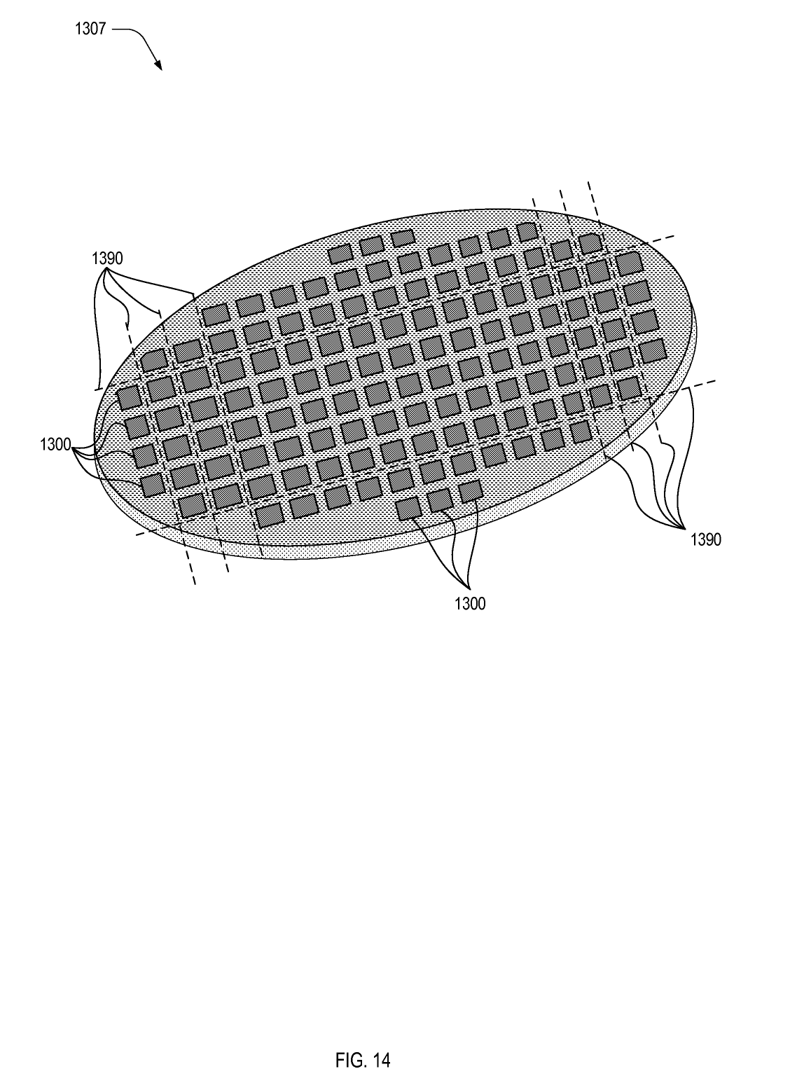

FIG. 14 is a perspective view of laminated wafer assembly 1307 shown with dicing planes 1390 superimposed thereon. Dicing planes 1390 are orthogonal to the plane of laminated wafer assembly 1307. For clarity of illustration, FIG. 14 does not include protective substrate 612, all dicing planes 1390, or all reference numerals for device-embedded image sensors 1300.

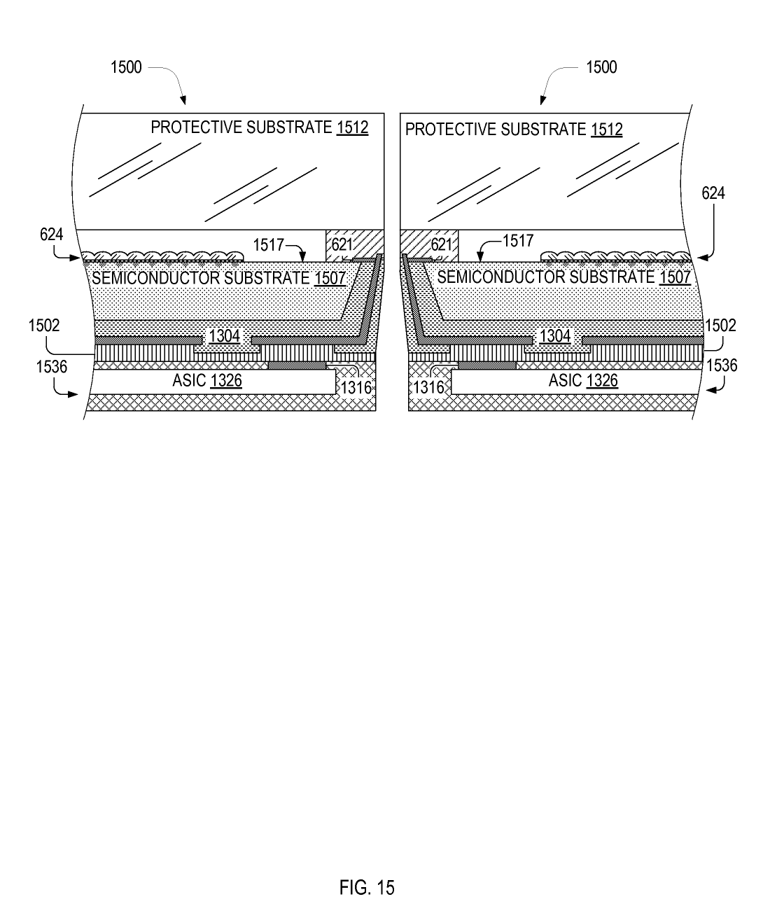

In optional step 518, method 500 singulates the CMOS image sensor wafer assembly to form a plurality of device-embedded image sensors. In an example of step 518, method 500 singulates laminated wafer assembly 1307 along dicing planes 1390 to form a plurality of device-embedded image sensors 1500, as shown in FIG. 15. Each device-embedded image sensor 1500 includes a protective substrate 1512, a semiconductor substrate 1507, an ACF 1502, and a bottom semiconductor substrate 1536, which are formed from protective substrate 612, semiconductor wafer 607, ACF 1302, and bottom semiconductor wafer 1336 respectively, of laminated wafer assembly 1307. Semiconductor substrate 1507 has a top surface 1517 that is the same as top surface 617 of semiconductor wafer 607. Optional step 518 may be performed by saw blade, laser cutting, or other die singulation methods known in the art.

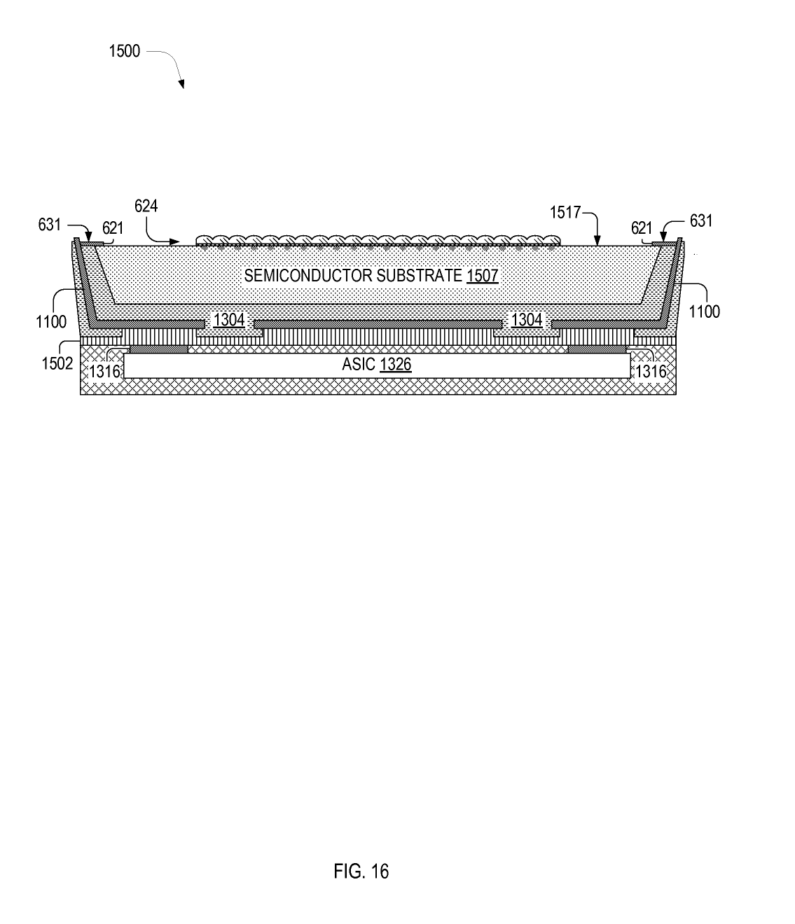

In optional step 520, method 500 removes the protective substrate. In an example of step 520, method 500 removes protective substrate 1512 from a device-embedded image sensor 1500, as shown as a cross-sectional view in FIG. 16. Step 520 enables device-embedded image sensor 1500 to be electrically connected to a PCB via top conductive pads 621. Each top conductive pad 621 has an exposed surface 631 on a top side of device-embedded image sensor 1500. The top side includes image sensor 624 and top conductive pads 621.

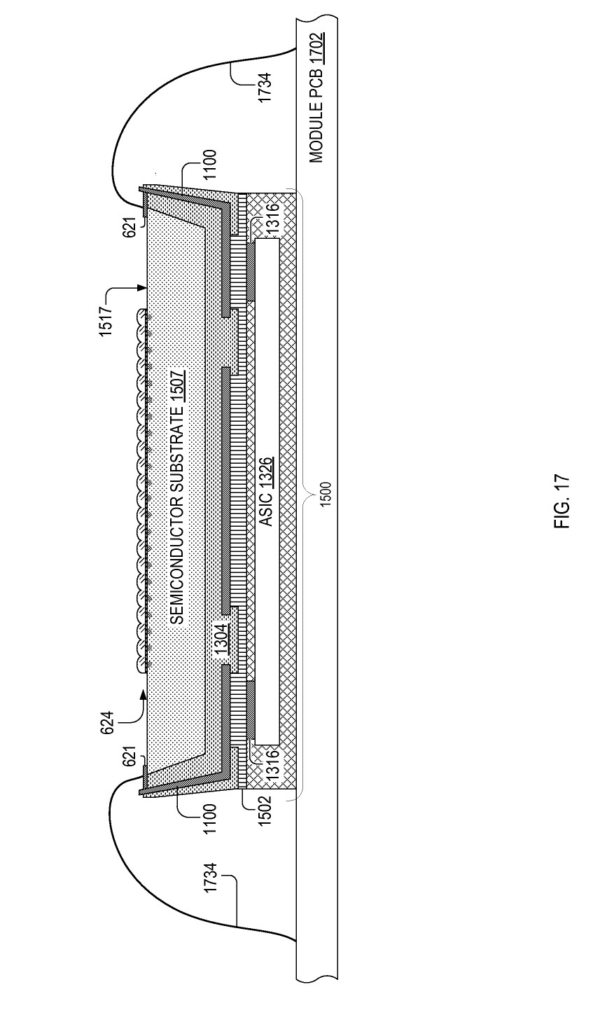

FIG. 17 is a cross-sectional view of device-embedded image sensor 1500 wire-bonded to a camera module PCB 1702. Wire bonds 1734 are similar to wire bonds 134, FIG. 1. Some of wire bonds 1734 are electrically connected to image sensor 624, and others are electrically connected to ASIC 1326 via top conductive pads 621. Wire bonds 1734 are bonded to top conductive pads 621 from above top surface 1517 of semiconductor substrate 1507. Top conductive pads 621 may also electrically connect with camera module PCB 1702 via a flip-chip method that includes gold-stud bonding (GSB).

Changes may be made in the above device-embedded image sensors and associated methods without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall there between.

1. A device-embedded image sensor comprising:
an image sensor formed in a first semiconductor substrate;
a top conductive pad formed on a top surface of the first semiconductor substrate; and
a semiconductor device formed in a second semiconductor substrate bonded to a bottom surface of the first semiconductor substrate, the semiconductor device electrically connected to the top conductive pad.

2. The device-embedded image sensor of claim 1, wherein one or both of (a) a redistribution layer (RDL) element and (b) a portion of anisotropic conductive material electrically connects a conductive pad of the semiconductor device to the top conductive pad.

3. The device-embedded image sensor of claim 1, the top surface of the first semiconductor substrate adjoining at least part of a bottom surface of the top conductive pad.

4. The device-embedded image sensor of claim 1, the semiconductor device comprising an application-specific integrated circuit (ASIC).

5. The device-embedded image sensor of claim 1, the image sensor being a CMOS image sensor.

6. The device-embedded image sensor of claim 1, the semiconductor device being electrically connected to the top conductive pad through an electrical connection path that traverses a side of the first semiconductor substrate.

7. The device-embedded image sensor of claim 6, the electrical connection path including a bottom conductive pad formed on the bottom surface of the first semiconductor substrate.

8. The device-embedded image sensor of claim 1, the semiconductor device being electrically connected to the top conductive pad through an electrical connection path that traverses through the first semiconductor substrate.

9. The device-embedded image sensor of claim 8, the electrical connection path including a bottom conductive pad formed on the bottom surface of the first semiconductor substrate.

10. A method for fabricating a plurality of device-embedded image sensors from a CMOS image sensor wafer assembly that includes an image sensor formed in a semiconductor substrate wafer and a conductive pad on a top side of the semiconductor substrate wafer, the method comprising the steps of:
exposing the conductive pad of the image sensor formed in the semiconductor substrate wafer by removing at least a portion of the semiconductor substrate wafer from beneath the conductive pad of the image sensor formed in the semiconductor substrate wafer;
forming an isolation layer over the removed portion of the semiconductor substrate wafer;
exposing a surface of the conductive pad by removing at least a portion of the isolation layer in contact thereto;
forming a patterned redistribution layer (RDL) having a plurality of RDL elements on the isolation layer such that the conductive pad is electrically connected to one of the plurality of RDL elements;
electrically isolating adjacent RDL elements;
laminating the CMOS image sensor wafer assembly and a semiconductor device wafer to form a sensor wafer assembly; and
singulating the sensor wafer assembly to form the plurality of device-embedded image sensors.

11. The method of claim 10, further comprising electrically connecting the conductive pad to a semiconductor device of the semiconductor substrate wafer.

12. The method of claim 10, the semiconductor substrate-wafer comprising one or more application-specific integrated circuits.

13. The method of claim 10, the step of exposing the conductive pad comprising forming a notch in the semiconductor substrate wafer beneath the top conductive pad.

14. The method of claim 13, the step of forming the notch-comprising etching the semiconductor substrate wafer.

15. The method of claim 10, the step of forming the isolation layer further comprising forming the isolation layer directly on the semiconductor substrate wafer.

16. The method of claim 10, the step of exposing a surface of the conductive pad comprising etching the isolation layer.

17. The method of claim 10, wherein the step of exposing a surface of the conductive pad comprises forming a through-silicon via through the semiconductor substrate wafer.

18. The method of claim 10, the step of electrically isolating comprising forming a plurality of isolation layer elements in a respective plurality of gaps between adjacent RDL elements.

19. The method of claim 10, the image sensor being a CMOS image sensor.
